(19) United States
(12) Patent Application Publication
(10) Pub. No.: US 2013/0280836 A1
(43) Pub. Date: Oct. 24, 2013

(54) METHOD AND SYSTEM FOR PRODUCING HIGH RESOLUTION PATTERNS IN REGISTRATION ON THE SURFACE OF A SUBSTRATE

(71) Applicants: Amalkumar P. Ghosh, Hopewell Junction, NY (US); Ronald W. Wake, Newburgh, NY (US)

(72) Inventors: Amalkumar P. Ghosh, Hopewell Junction, NY (US); Ronald W. Wake, Newburgh, NY (US)

(73) Assignee: EMAGIN CORPORATION, Hopewell Junction, NY (US)

(21) Appl. No.: 13/451,961

(22) Filed: Apr. 20, 2012

(51) Int. Cl. H01L 33/50; H01L 21/31

(52) U.S. Cl. 438/29; 438/763; 257/E21.24; 257/E33.061

(57) ABSTRACT

A method of selectively applying a material to a surface of a substrate from a stamp with a raised surface using an energy activated release layer is provided. The release layer is applied to at least a first portion of a surface of the stamp. A layer of the material is applied to the raised surface of the stamp. The raised surface of the stamp is placed in contact with the surface of the substrate such that the material layer is situated therebetween. Thereafter, the release layer is activated with energy, causing the material layer to release from the raised surface of the stamp, and to adhere to the surface of the substrate. Alternatively, the entire stamp surface may be coated with the release layer and the release layer may be selectively activated in the areas in which the material on the stamp surface is in contact with the substrate.

### CROSS-REFERENCE TO RELATED APPLICATIONS

Not Applicable

### STATEMENT REGARDING FEDERALLY SPONSORED RESEARCH OR DEVELOPMENT

Not Applicable

### BACKGROUND OF THE INVENTION

1. Field of the Invention

The present invention relates to selectively transferring color forming material layers to a substrate using a stamp, and more particularly to the use of an energy activated release layer to facilitate the transfer of the material layers from the raised portions of the stamp to provide a highly precise pattern on the substrate.

2. Description of Prior Art

An OLED device typically includes a stack of thin layers formed on a substrate. In the stack, a light-emitting layer of a luminescent organic solid, as well as adjacent semiconductor layers, is sandwiched between a cathode and an anode. The light-emitting layer may be selected from any of a multitude of fluorescent and/or phosphorescent organic solids. Any of the layers, and particularly the light-emitting layer, may consist of multiple sub layers.

In a typical OLED, either the cathode or the anode, or both, is transparent. The films may be formed by evaporation, spin casting, other appropriate polymer film-forming techniques, or chemical self-assembly. Thicknesses typically range from a few monolayers to about 1 to 2,000 angstroms. Protection of OLED against oxygen and moisture can be achieved by encapsulation of the device. The encapsulation can be obtained by means of a single thin-film layer situated on the substrate, surrounding the OLED.

High resolution active matrix displays may include millions of pixels and sub-pixels that are individually addressed by the drive electronics. Each sub-pixel can have several semiconductor transistors and other IC components. Each OLED may correspond to a pixel or a sub-pixel, and these terms are used interchangeably herein.

In devices that either capture or display full color images, it is required to precisely pattern color specific materials onto individual pixels (picture elements) of the device. These color specific materials can be primary colors (red, green, and blue), complimentary colors (cyan, magenta, and yellow), or some combination thereof. Examples of image capture devices include electronic image sensors, either CCD (charge coupled device) or CMOS (complementary metal oxide semiconductor). Display device types include LCD (liquid crystal display) and electroluminescence (EL). EL devices come in many varieties including light emitting diodes (LED), organic light emitting diodes (OLED), and polymer light emitting diodes (PLED).

In electronic image sensors, both CCD and CMOS, the color specific materials are almost exclusively color filters that simply isolate regions of the electromagnetic spectrum. This enables individual pixels to sense only certain colors thus allowing the reconstruction of a full color image.

It is widely known that this filtering technique is very inefficient use of the available light since each filter only allows a certain part of the electromagnetic spectrum to pass. The remainder of the spectrum is either absorbed or reflected, resulting in lost information. Much effort has gone into minimizing this loss by taking advantage of the fact that, in image sensors, the captured information in each pixel is further processed before being sent to a display device. Since the most important image information for reconstruction of an accurate reproduction is the luminance, color filter patterns tend to maximize the green and white components. Only minimal amount of red and blue are needed to accurately reproduce the color information.

There are both similarities and differences between image sensors and image display devices. In display devices, the image is directly viewed by the observer. Thus, there is no opportunity to process the image once it has gone through the color filter. This necessitates the use of filters with red, green, and blue characteristics that are directly pleasing to the standard observer.

Color displays can be of two basic types. The first type generates light of the same spectral distribution, usually white, from all of the pixels. The light then passes through a patterned color filter to obtain the necessary color differentiation for image display. This type of display is relatively easy to produce since only one type of light producing material is needed and it doesn't have to be patterned. The only patterning required is for the electrode and color filter. Both of these are readily accomplished with standard photolithographic techniques.

However, this type of display does suffer from the same inefficient use of available light as does the image sensor. In the case of electroluminescent displays, there is a second option. This option is to use different light generating materials for each color. Since the entire light output is used for each pixel, this results in very efficient use of the light and potentially brighter displays. However, this option does require the patterning of each type of color generating material. For electroluminescent devices, these materials usually are not able to withstand standard photolithographic patterning.

Electroluminescent materials are typically vapor deposited as thin films. These thin films are typically less than 1000 Å in thickness and the quality of the interface between stacked thin films is critical for the charge (electrons and holes) transport necessary for efficient electroluminescence. The deposition of electroluminescent materials in a patterned fashion has typically been done using a shadow mask technique as taught by Nagayama et al. in U.S. Pat. No. 5,742,129.

The shadow mask technique is simply the deposition of materials through openings in a hard mask which is positioned in close proximity to the device and in proper registration. This technique has worked well for relatively small devices with moderate resolution requirements.

However, the resolution capabilities are limited since the material is diffused through an opening in a mask positioned some distance from the device. Hard contact of the mask and device is not advisable since it will likely cause damage to the device layers already present and increases the probability for contamination. This diffusion is also done in a vacuum system and is non-directional. The shadow mask type of deposition dictates that the gap between the mask and device be tightly controlled to obtain consistent pattern dimensions. Nagayama et al. teach that this consistent gap can be obtained by forming ramparts on the device between the pixels, which allows consistent hard contact between the mask and device but limits the resolution since the ramparts take up valuable space.

Another limitation of the shadow mask technique is the size of the device that can be produced. Vapor deposition processes are relatively slow and require high vacuum conditions. Thus, it is advantageous to perform these depositions on substrates that are as large as possible. The shadow masks would need to be of the same lateral dimension and remain thin for efficient deposition. As pixel dimensions are reduced, the production of these masks becomes very difficult and their structural integrity is reduced. In addition, accurate registration and gap control become infeasible.

Tang et al., in U.S. Pat. No. 5,294,869, disclose a process for the fabrication of a multicolor organic electroluminescent display using a shadow masking method in which the shadow mask with an appropriate topological feature is an integral part of the device structure. This integral shadow mask method uses a glass substrate bearing a set of laterally spaced indium tin oxide anode electrodes. Upon this substrate, sets of pillars (integral shadow mask) made of insulating materials and fabricated by conventional photolithographic methods are positioned to provide a template for the subsequent deposition of the organic layers as well as the cathode electrodes. The multi-color organic electroluminescent medium is deposited and patterned by controlling the angular position of the substrate with respect to the deposition vapor stream. Likewise, the cathode electrode is deposited and patterned on top of the organic electroluminescen medium by controlling the angular relationship between the metal vapor stream and the substrate.

This method is compatible with the photolithographic process and provides a novel procedure for patterning the organic electroluminescent medium to form a multicolor electroluminescent panel. However, this method requires an integral shadow mask of multi-level topology which may be difficult to produce, and a vapor deposition process which requires certain complex geometrical arrangements between the vapor sources and substrate.

Tang et al., in U.S. Pat. No. 6,066,357, teach the use of ink jet as a method for directly patterning electroluminescent materials not requiring a mask. This invention describes deposition of dopant materials by ink jet onto a host surface with subsequent diffusion into the host. This would require a liquid formulation for the dopant which limits the choice of materials. Also, the diffusion step will reduce the obtainable resolution.

Obtaining higher resolution is addressed by Tang et al. in U.S. Pat. Nos. 5,688,551 and 5,851,709 where the electroluminescent multi-color materials are deposited by close spaced sublimation from a donor to the substrate. The patterned transfer is accomplished by one of two methods. Either the donor sheet is patterned with a light-activated heat source or it is unpatterned. In the former case, thermally transferring the materials is accomplished using a blanket exposure with light causing thermal heating in the areas of the donor where transfer is desired. In the latter case, an unpatterned donor is exposed with a laser beam in the desired pattern. These methods allow high resolution patterning of electroluminescent materials. However, the final light emitting device must have a dopant mixed with a host material to give a good emission. It is difficult to co-evaporate two or more materials simultaneously and maintain a constant, controlled ratio.

The previous decade has witnessed a concerted effort in the development of technology to advance electronics manufacturing both by improving resolution and lowering costs. This has resulted in the development of stamping technologies. These stamping technologies show promise for high resolution imaging since the limitation is in the capability to produce the stamp. Since stamps can be formed using low volume technologies such as electron beam, x-ray, and ion beam lithography, patterns as small as 10 nanometers have been produced.

There are basically two types of stamping technology, either imprint or contact printing. The former involves pressing a stamp into an amorphous material which conforms to the stamp producing a 3D structure. This technique is useful only for a single layer pattern. Imprinting adjacent patterns on the same level is not possible.

The latter stamping technology is essentially the same as the printing technology that has been used for centuries. A stamp with protruding features is “inked” with the material to be deposited then pressed against a receiving substrate. Only the material on the protruding portions of the stamp is transferred to the substrate resulting in a pattern. This technology does have the potential to produce multiple patterns on the same level since it involves only offsetting the stamp for subsequent patterns.

The potential of contact printing technology has been recognized for the production of electroluminescent devices. Kim et al. in U.S. Pat. No. 7,964,439 disclose the deposition of an organic material from a patterned stamp to an organic layer over a substrate. In order to improve transfer efficiency, the organic layer over the substrate is a thin layer of the same material to be deposited. In addition, an adhesion reduction layer is required to be applied to the stamp prior to electroluminescent material deposition. In this manner the van der Waals forces of like materials facilitates the transfer from the stamp to the substrate. The requirement of a like material already present on the substrate limits the design of the electroluminescent material stack for efficient luminescence.

Coe-Sullivan et al. in U.S. Patent Application 2008/0001167 disclose the transfer of a semiconductor nanocrystal monolayer from a stamp to a substrate. Although the pre-existing presence of a like material on the substrate is not required, there is a need to pretreat the stamp surface to promote the material transfer upon contact with the substrate. Thus the prior art is dependent on the relative adhesion of the electroluminescent material to the stamp and substrate for efficient transfer. Since infinite selectivity is unlikely, there is a real possibility for incomplete transfer and yield reduction with this prior art transfer technique.

### BRIEF SUMMARY OF THE INVENTION

It is therefore a prime object of the present invention to provide a method and a system for producing high resolution patterns in registration on the surface of a substrate.

It is another object of the present invention to provide a method and a system for producing high resolution patterns in registration on the surface of a substrate by the deposition of an organic material from a patterned stamp.

It is another object of the present invention to provide a method and a system for producing high resolution patterns in registration on the surface of a substrate by the deposition of an organic material from a patterned stamp wherein it is not necessary to form a layer of the same organic material on the surface of the substrate before deposition.

It is another object of the present invention to provide a method and a system for producing high resolution patterns in registration on the surface of a substrate by the deposition of an organic material from a patterned stamp utilizing an energy activated release layer.

It is another object of the present invention to provide a method and a system for producing high resolution patterns in registration on the surface of a substrate by the deposition of an organic material from a patterned stamp, wherein the energy activated release layer is interposed between the stamp surface and the organic material.

It is another object of the present invention to provide a method and a system for producing high resolution patterns in registration on the surface of a substrate by the deposition of an organic material from a patterned stamp to provide very high efficiency OLED displays having a very long operational lifetime.

It is another object of the present invention to provide a method and a system for producing high resolution patterns in registration on the surface of a substrate by the deposition of an organic material from a patterned stamp to enable manufacturing of ultra-high resolution micro-displays with better control of the emitted light spectra.

The above objects are obtained from the present invention which relates to a method of selectively applying a material to a surface of a substrate from a stamp with a raised surface and using an energy activated release layer to facilitate the release of the material from the surface of the stamp. The method includes the steps of: applying the release layer to at least a raised portion of a surface of the stamp; applying a layer of the material to the raised surface of the stamp; causing the raised surface of the stamp to contact the surface of the substrate such that the material layer is situated therebetween; and activating the release layer with energy causing the material layer to release from the raised surface of the stamp and to adhere to the surface of the substrate.

In situations where the release layer is applied on substantially the entire surface of the stamp, prior to applying the material layer to the raised surface of the stamp, the release layer on a non-raised portion of the stamp may be selectively removed or deactivated.

The step of activating the release layer may include selectively applying the energy to the release layer on the raised portion of the stamp.

In accordance with another aspect of the present invention, a method of producing high resolution patterns on a surface of a substrate is provided. The method includes the steps of: coating the surface of the stamp patterned with topography with a release layer adapted to be activated by energy from a source to release from the surface of the stamp; coating the release layer with a material to be applied to the surface of the substrate; causing the coated surface of the stamp to contact the surface of the substrate; and activating the release layer with energy from the source to selectively release the material coated on the stamp surface onto the substrate only in those areas where the material on the stamp surface and the surface of the substrate are in contact.

The steps of the method may be repeated using the same substrate and sequentially transferring multiple stacks of material in laterally different locations corresponding to different functional areas of the substrate.

The substrate is preferably a pixelated device capable of either sensing images or displaying images.

The release layer is selectively patterned on the stamp surface allowing the unpatterned activation bringing about the transfer of the material to the substrate.

The release layer is unselectively coated on the stamp surface thus requiring a patterned activation bringing about the transfer of the material to the substrate.

The stamp may be made entirely of an elastic material. Alternatively, the stamp may have multiple layers, at least one of which is elastic.

The material to be transferred may be a stack of various layers of materials of different structure and function.

The material to be transferred may be organic or inorganic, the latter including metals and oxides.

The material to be transferred may be a stack of different types of materials which, in combination with the substrate, form an OLED device.

The OLED device may be a top emitting display or a bottom emitting display.

### BRIEF DESCRIPTION OF THE DRAWINGS

To these and to such other objects that may hereinafter appear, the present invention relates to a method and system for producing high resolution patterns in registration on the surface of a substrate as described in detail in the following specification and recited in the annexed claims, taken together with the accompanying drawings, in which like numerals refer to like parts and in which:

FIG. 1 illustrates the steps in the fabrication of the stamp according to an embodiment of this invention;

FIG. 2 shows the structure of the stamp according to an additional embodiment of this invention;

FIG. 3 illustrates the steps in the coating of the stamp according to an embodiment of this invention;

FIG. 4 illustrates the steps in the coating of the stamp according to an additional embodiment of this invention;

FIG. 5 illustrates the steps in transferring the organic material from the stamp to the substrate according to an embodiment of this invention; and

FIG. 6 illustrates the steps in transferring the organic material from the stamp to the substrate according to an additional embodiment of this invention.

### DETAILED DESCRIPTION OF THE INVENTION

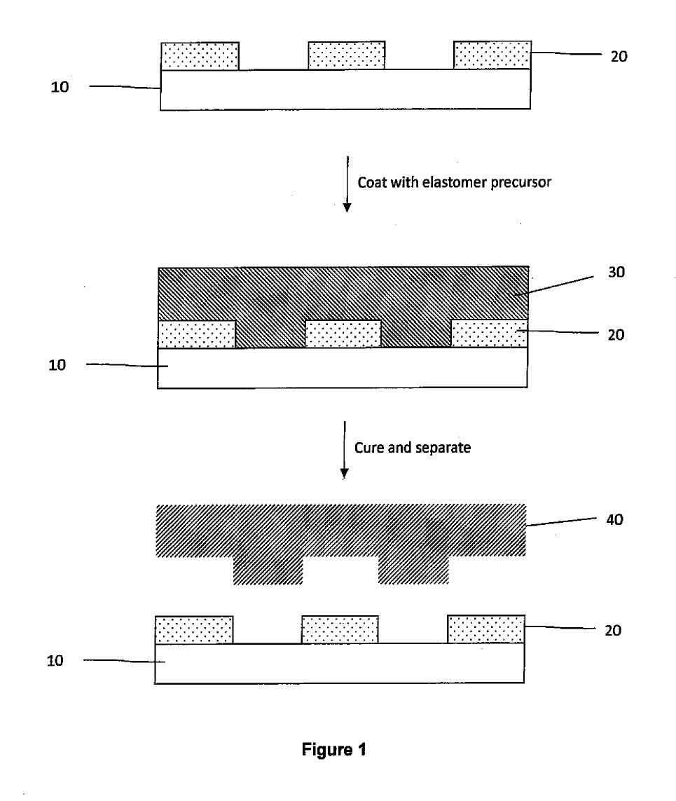

With reference to the accompanying drawings, a detailed description of the preferred embodiments of the present invention will now be made. FIG. 1 shows the steps in the fabrication of the stamp. The process starts with a rigid substrate 10 on which the desired pattern features 20 have been formed. The materials used are not critical to the overall process however a logical choice for the substrate would be silicon in the form of a wafer commonly used in the semiconductor industry. Process equipment and technology are readily available for forming features either on or etched into the surface of silicon wafers. If the pattern is etched into the silicon, then the indicated features 20 would be of the same material, silicon, as the substrate 10. If the pattern was formed on the silicon, then a likely material would be silicon dioxide which is readily formed and patterned on silicon.

The next step is to coat the structure with a curable liquid material 30 that, once cured, forms an elastomeric solid. The most common choice for this material is poly(dimethylsiloxane) (PDMS) which is available commercially as Sylgard® 184 from Dow Corning Corporation. Once cured, the PDMS can be peeled off of the substrate to form a stand-alone elastomeric stamp 40.

PDMS stamps are well known and widely used in contact lithography for printing relatively large images (>100 μm). The soft nature of the material causes structures smaller than 1 μm to merge or collapse during the contact printing process. Thus for contact lithography to produce images needed for advanced electronic image sensors and displays an improved stamp structure is necessary.

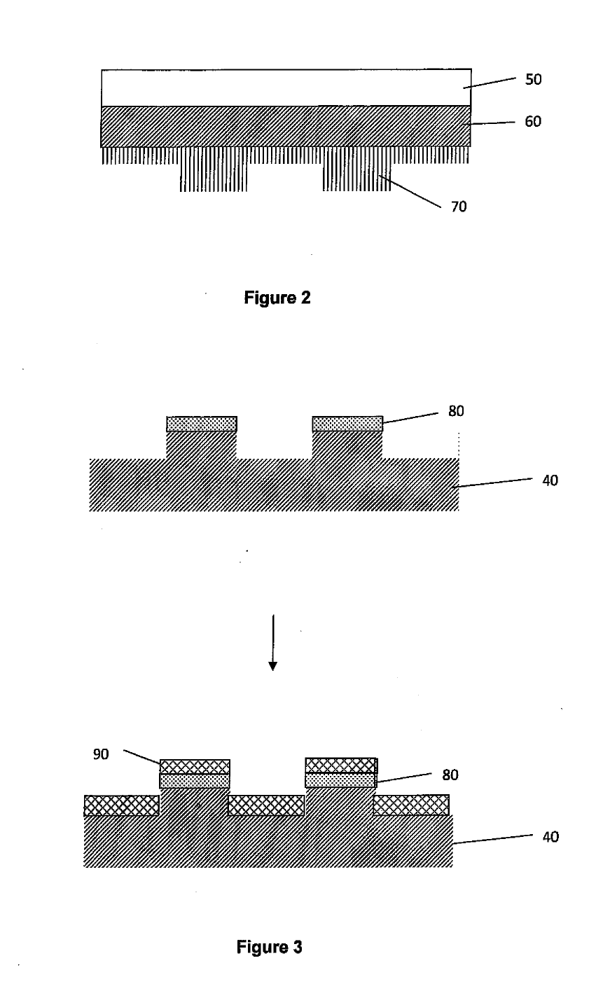

FIG. 2 shows the preferred structure of a stamp to be used for high resolution contact printing. The base of the stamp 50 is a hard material to give the stamp structural stability. This material is also preferably transparent thus it could be preferably glass. The intermediate layer 60 is included to supply the elasticity needed to conform to any non-planarity in the substrate. This material could be PDMS. The surface of the stamp 70 forms a relatively stiff pattern that will not merge or collapse during the printing process. This material is preferably a polymeric material, of higher modulus than PDMS, that can be readily patterned.

Once formed, the stamp must be coated with the necessary materials. This is illustrated in FIG. 3 for a preferred embodiment of this invention. For simplicity the illustration shows the stamp 40 as solid PDMS as in FIG. 1. It will be recognized that this may not be the most optimum structure for the stamp as described above and illustrated in FIG. 2. The first material coated on the stamp is the release layer 80 which is preferentially deposited only on the protruding areas of the stamp however this is not a requirement as will be seen. Depositing the release layer only on the protruding areas of the stamp could be accomplished by contact printing. After the selective deposition of the release layer, the material 90 to be transferred to the substrate is deposited on the stamp in a blanket, unpatterned fashion. This is easily accomplished by either vapor deposition for solid materials or by spin or spray application for liquids with subsequent drying.

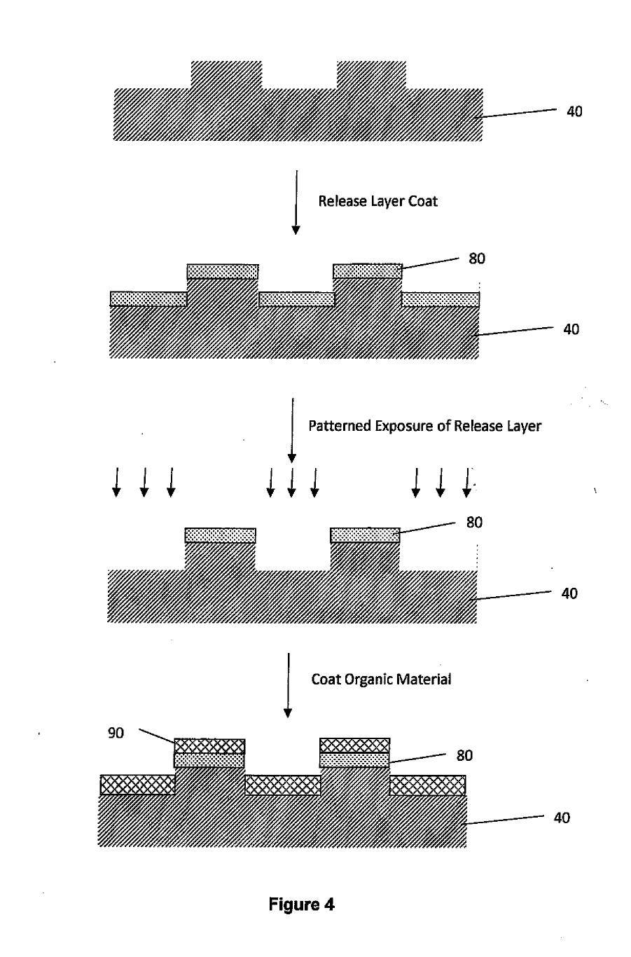

FIG. 4 illustrates another preferred embodiment for the coating of the stamp. The difference is in the patterning of the release layer 80. In this embodiment the release layer 80 is blanket coated over the entire surface of the stamp. This is preferably accomplished by spin coating but spray coating can also be used depending on the type of material used. The next step takes advantage of the reactivity of the release layer 80. The release layer 80 is exposed through a mask or by a focused laser beam so that only the recessed areas of the stamp are exposed. This exposure causes the release layer 80 to vaporize from the recessed areas thus leaving it remaining only on the protruding areas of the stamp. After patterning of the release layer 80, the material to be transferred 90 is deposited in an unpatterned as described above and in FIG. 3.

There are various types of materials that can be used as the release layer. The requirement is that the action of an energy source, e.g.—light or heat, causes a physical or chemical change resulting in the release of any material coated on its surface. The preferential change would be vaporization since this would cleanly separate the material from the stamp and leave the stamp ready for reuse. Also, the vaporization would leave the transferred material free from any debris that could affect its color defining function in the final device. Another type of change would be melting or a combination of vaporization and melting. These would be less desirable due to the possible residue remaining thus necessitating further cleaning steps.

Examples of materials that could be used as photo-activated release layers include aryltriazene photopolymers as described by Fardel et al. (Applied Surface Science, 255, 5430-5434 (2009)) and references cited therein. These materials readily decompose to nitrogen and small, volatile organic fragments under the influence of XeCl excimer laser irradiation.

The application described in the above cited references is the explosive ejection of exposed portions of a solid layer of material to project it onto a nearby substrate. This explosive force is produced due to the buildup of trapped gases underneath the exposed portion on the continuous layer. The resulting ripping out of portions of the continuous layer will produce jagged edges on the transferred portion. The edges are claimed to be smooth and, relative to the features sizes of 500 μm used to demonstrate the technology, they may be. However, for high resolution imaging and display devices the roughness would be a very high percentage of the feature sizes and unacceptable. The present invention does not use a continuous layer for the release layer. The lateral portions of the stamp protrusions provide a release area for the vapors produced thus resulting in a release of the material and not an explosive expulsion.

Another example of a class of materials that could be used as photo-activated release layers is polyols. These include polyaldehydes, polyethylene oxide, and polyethylene glycols. Choi (U.S. Pat. No. 5,001,036) describes examples of these types of materials as photorelease layers. Also, Willson et al. (Proc. IUPAC 28th Macromolecular Symp., 1982) describe polyaldehyde formulations used as self-developing photoresists.

Still another example of a material that could be used as a release layer is amorphous silicon. It is known to both melt and release hydrogen under the influence of a XeCl excimer laser (see French et al., U.S. Pat. No. 8,027,000).

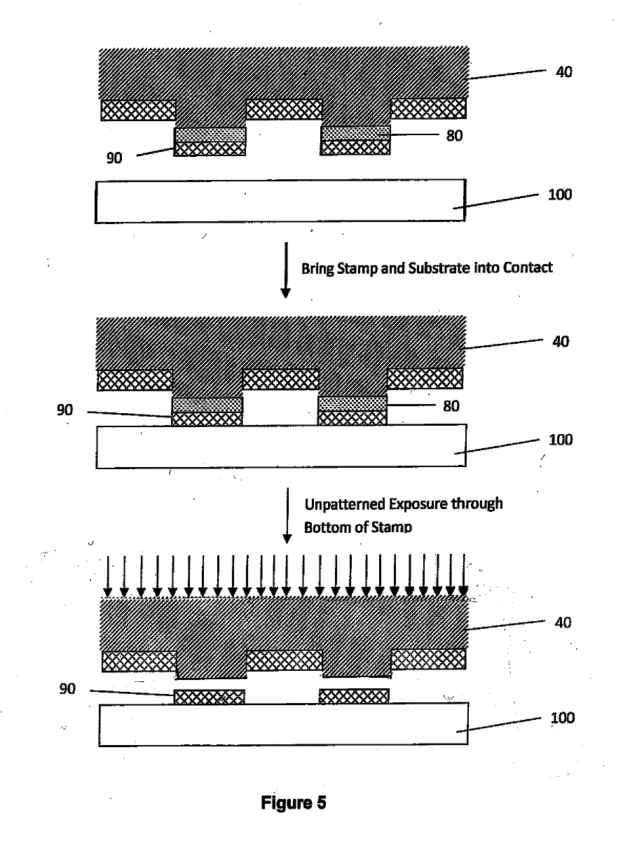

Once the stamp has been produced and coated the transfer process occurs. This is illustrated in FIG. 5 in which it will again be noted that the stamp 40 is illustrated as one solid material however, as described above and illustrated in FIG. 2, the preferred structure may be a multi-layer of rigid and elastomeric materials if high resolution patterns are desired. The process begins by bringing the stamp 40 into close proximity to the substrate 100. This allows the aligning of the stamp for proper placement of the patterns of color defining materials. Once aligned, the stamp 40 (which at this point is coated with the release layer 80 and the material 90 to be deposited) is brought into soft contact with the substrate 100 at which point the stamp is treated with an unpatterned energy source, through its surface opposite from the substrate, of sufficient energy to activate the release layer 80. This exposure causes the release layer 80 to be vaporized or melted. In either case this brings about the release of the color defining materials 90 from the stamp 40 to the surface of the substrate 100.

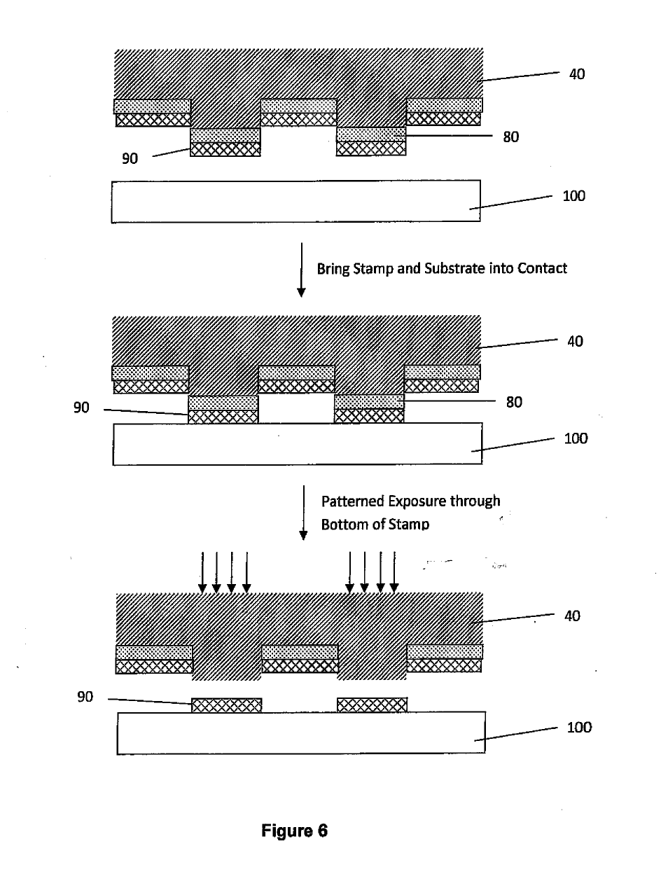

FIG. 5 illustrates the preferred embodiment of this invention whereby the release layer 80 is patterned on the stamp. This allows the energy source to be unpatterned thus simplifying this step in the overall process. However, another embodiment of this invention is the simplification of the stamp production by not requiring the release layer 80 to be patterned. This embodiment is illustrated in FIG. 6 wherein the stamp consists of unpatterned layers of both the release layer 80 and the color defining material 90. When the stamp and substrate are brought into contact the patterned transfer to the substrate occurs by using a patterned exposure to an energy source whereby only the protruding portions of the stamp are subjected to the activating energy.

The stamping techniques described above can be utilized to provide high resolution displays on a substrate including a first light emitting sub-pixel situated on the substrate surface. The first light emitting sub-pixel includes a first base electrode, a first transparent electrode, and a first light-emissive layer interposed between the first base electrode and the first transparent electrode. The first light-emissive layer may include a fluorescent material, which may be adapted to emit blue light.

Then, a second light emitting sub-pixel is formed on the substrate surface. The second light emitting sub-pixel includes a second base electrode, a second transparent electrode, and a second light-emissive layer interposed between the second base electrode and the second transparent electrode. The second light-emissive layer may include a phosphorescent material, which may be adapted to emit red light.

After that, a third light emitting sub-pixel is formed on the substrate surface. The third light emitting sub-pixel includes a third base electrode, a third transparent electrode, and a third light-emissive layer interposed between the third base electrode and the third transparent electrode. The third light-emissive layer may include a phosphorescent material, which may be adapted to emit green light. Upon completion, at least one of the first, second and third light emitting sub-pixels is activated.

A computer system can perform the steps described above. The computer contains processor which controls the operation of the computer by executing computer program instructions which define the operation, and which may be stored on a computer-readable recording medium. The computer program instructions may be stored in storage (e.g., a magnetic disk, a database) and loaded into a memory when execution of the computer program instructions is desired. Thus, the computer operation will be defined by computer program instructions stored in memory and the computer will be controlled by the processor to execute the computer program instructions.

The computer also includes one or more network interfaces for communicating with other devices, for example other computers, servers, or websites. The network interfaces may, for example, be a local network, a wireless network, an intranet, or the Internet. The computer also includes input/outputs, which represent devices which allow for user interaction with the computer (e.g., display, keyboard, mouse, speakers, buttons, webcams, etc.). One skilled in the art will recognize that an implementation of an actual computer will contain other components as well, and that only a high level representation of some of the components of such a computer is described herein for illustrative purposes.

While only a limited number of preferred embodiments of the present invention have been disclosed for purposes of illustration, it is obvious that many modifications and variations could be made thereto. It is intended to cover all of those modifications and variations which fall within the scope of the present invention, as defined by the following claims.

We claim:

1. A method of selectively applying a material to a surface of a substrate from a stamp with a raised surface and using an energy activated release layer, the method comprising the steps of:
applying the release layer to at least a portion of a surface of the stamp including a raised surface;
applying a layer of the material to the raised surface of the stamp;
causing the raised surface of the stamp to contact the surface of the substrate such that the material layer is situated therebetween; and
activating the release layer with energy causing the material layer to release from the raised surface of the stamp and to adhere to the surface of the substrate.

2. The method of claim 1, wherein said portion of the stamp surface comprises a non-raised surface and further comprising, prior to applying the material layer to the raised surface of the stamp, one of selectively removing and selectively deactivating the release layer on said non-raised surface, wherein the step of applying the release layer comprises applying the release layer on substantially the entire surface of the stamp.

3. The method of claim 2, wherein the step of activating the release layer further comprises selectively applying the energy to the release layer on the raised surface of said portion of the stamp.

4. The method of claim 1, wherein the step of activating the release layer further comprises selectively applying the energy to the release layer on the raised portion of the stamp.

5. A method of producing high resolution patterns on a surface of a substrate, comprising:
(a) coating the surface of the stamp patterned with topography with a release layer adapted to be activated by energy from a source to release from the surface of the stamp;
(b) coating the release layer with a material to be applied to the surface of the substrate;
(c) causing the coated surface of the stamp to contact the surface of the substrate; and
(d) activating the release layer with energy from the source to selectively release the material coated on the stamp surface onto the substrate only in those areas where the material on the stamp surface and the surface of the substrate are in contact.

6. The method of claim 5, wherein steps (a) thru (d) are repeated using the same substrate and sequentially transferring multiple stacks of material in laterally different locations corresponding to different functional areas of the substrate.

7. The method of claim 1, wherein in the substrate is a pixelated device capable of at least one of sensing images and displaying images.

8. The method of claim 1, wherein the release layer is selectively patterned on the stamp surface allowing the unpatterned activation bringing about the transfer of the material to the substrate.

9. The method of claim 1, wherein the release layer is unselectively coated on the stamp surface thus requiring a patterned activation bringing about the transfer of the material to the substrate.

10. The method of claim 1, wherein the stamp is made entirely of an elastic material.

11. The method of claim 1, wherein the stamp consists of multiple layers, at least one of which is elastic.

12. The method of claim 1, wherein the material to be transferred is a stack of various layers of materials of different structure and function.

13. The method of claim 1, wherein the material to be transferred is organic.

14. The method of claim 1, wherein the material to be transferred is inorganic including metals and oxides.

15. The method of claim 1, wherein the material to be transferred is a stack of different types of materials that, in combination with the substrate, form an OLED device.

16. The method of claim 15, wherein the OLED device is top emitting.

17. The method of claim 15, wherein the OLED device is bottom emitting.

18. The method of claim 15, wherein the OLED device comprises:
a first light emitting sub-pixel situated on said substrate surface and comprising a first base electrode, a first transparent electrode, and a first light-emissive layer interposed between said first base electrode and said first transparent electrode, said first light-emissive layer comprising fluorescent material; and
a second light emitting sub-pixel situated on said substrate surface and comprising a second base electrode, a second transparent electrode, and a second light-emissive layer interposed between said second base electrode and said second transparent electrode, said second light-emissive layer comprising phosphorescent material.

19. The method of claim 18, wherein:
said first light-emissive layer is adapted to emit blue light; and
said second light-emissive layer is adapted to emit one of red light and green light.

20. The method of claim 19, wherein the OLED device further comprises:
a third light emitting sub-pixel situated on said substrate surface and comprising a third base electrode, a third transparent electrode, and a third light-emissive layer interposed between said third base electrode and said third transparent electrode, and said third light-emissive layer comprising phosphorescent material;
wherein said second light-emissive layer is adapted to emit red light; and
wherein said third light-emissive layer is adapted to emit green light.
